(19) United States
(12) Patent Application Publication
(10) Pub. No.: US 2022/0044067 A1
(43) Pub. Date: Feb. 10, 2022

(54) DATA ANALYSIS APPARATUS AND DATA ANALYSIS METHOD

(71) Applicant: Kioxia Corporation, Tokyo (JP)

(72) Inventor: Masahiro HAYASHI, Yokkaichi (JP)

(73) Assignee: Kioxia Corporation, Tokyo (JP)

(21) Appl. No.: 17/155,443

(22) Filed: Jan. 22, 2021

(30) Foreign Application Priority Data
Aug. 5, 2020 (JP) 2020-133291

(51) Int. Cl. G06K 9/62; G06N 7/00

(52) U.S. Cl. CPC G06K 9/6232; G06N 7/005; G06K 9/6261

(57) ABSTRACT

A data analysis apparatus according to the present invention includes an extractor configured to extract, regarding a first feature amount among a plurality of feature amounts as an objective variable, a second feature amount having a linear relation or a nonlinear relation with the first feature amount as an explanatory variable by using analysis-target data that is sampled for the feature amounts. An adjuster is configured to set a node of base conversion for the second feature amount based on a significant difference between a linear regression result obtained by linear regression of the second feature amount and a nonlinear regression result obtained by nonlinear regression of the second feature amount. An analyzer is configured to divide the second feature amount based on the node set by the adjuster and perform regression analysis to generate a regression equation that represents the objective variable by the explanatory variable.

### CROSS REFERENCE TO RELATED APPLICATIONS

This application is based upon and claims the benefit of priority from the prior Japanese Patent Application No. 2020-133291, filed on Aug. 5, 2020, the entire contents of which are incorporated herein by reference.

### FIELD

The embodiments of the present invention relate to a data analysis apparatus and a data analysis method.

### BACKGROUND

It is considered that a regression model is constructed using an important quality indicator in a semiconductor manufacturing process or the like as an objective variable and measured data of various types of feature amounts as explanatory variables so as to estimate the influence of the feature amounts on the quality indicator.

However, in a case of using a conventional analysis method such as Lasso (Least Absolute Shrinkage and Selection Operator) based on conventional B-spline base conversion, for example, all the explanatory variables are subjected to B-spline base conversion, and therefore a linear component that does not need to be subjected to B-spline base conversion is also converted. In this case, the number of explanatory variables becomes larger than the number of samples, thus causing a problem of lowering reliability of analysis. In addition, since the same number of divisions is applied to all the explanatory variables in B-spline base conversion, the number of divisions for all the explanatory variables increases in order to construct a highly reliable regression model. Accordingly, if a highly reliable regression model is constructed, an analysis time becomes long.

### BRIEF DESCRIPTION OF THE DRAWINGS

FIG. 1 is a block diagram illustrating a configuration example of a data analysis apparatus according to the present embodiment;

FIGS. 2A to 2F are graphs illustrating specific examples of a parameter and an important feature amount;

FIG. 3 is a table representing an example of a correlation coefficient between the parameter and the important feature amount and a DC value;

FIG. 4 is a conceptual diagram illustrating a method of determining whether a parameter is a linear parameter or a nonlinear parameter;

FIGS. 5 and 6 are conceptual diagrams illustrating a method of setting the number of nodes for a nonlinear parameter;

FIG. 7 is a conceptual diagram illustrating data analysis according to the present embodiment;

FIG. 8 represents tables of regression coefficients obtained by Lasso, Random Forest, B-spline Lasso, and the data analysis method according to the present embodiment; and

FIG. 9 represents a table of coefficients of determination R² and calculation times obtained by Lasso, Random Forest, B-spline Lasso, and the data analysis method according to the present embodiment.

### DETAILED DESCRIPTION

Embodiments will now be explained with reference to the accompanying drawings. The present invention is not limited to the embodiments. In the present specification and the drawings, elements identical to those described in the foregoing drawings are denoted by like reference characters and detailed explanations thereof are omitted as appropriate.

A data analysis apparatus according to the present invention includes an extractor configured to extract, regarding a first feature amount among a plurality of feature amounts as an objective variable, a second feature amount having a linear relation or a nonlinear relation with the first feature amount as an explanatory variable by using analysis-target data that is sampled for the feature amounts. An adjuster is configured to set a node of base conversion for the second feature amount based on a significant difference between a linear regression result obtained by linear regression of the second feature amount and a nonlinear regression result obtained by nonlinear regression of the second feature amount. An analyzer is configured to divide the second feature amount based on the node set by the adjuster and perform regression analysis to generate a regression equation that represents the objective variable by the explanatory variable.

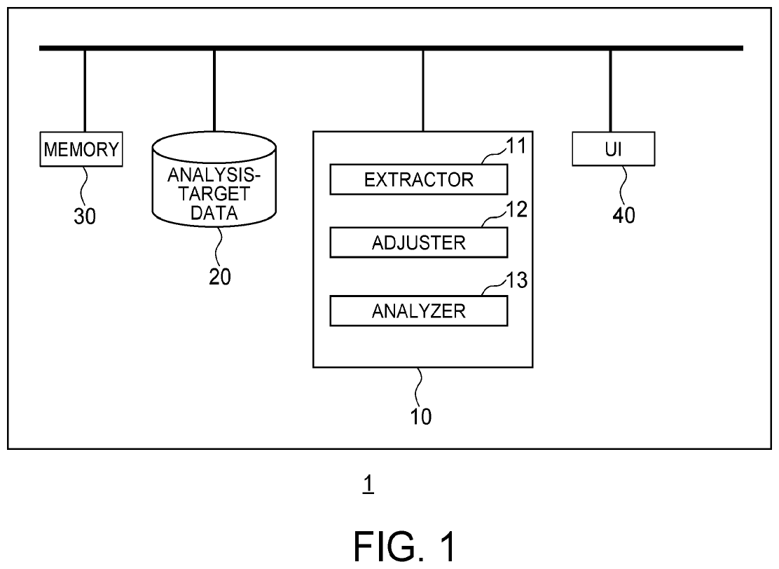

FIG. 1 is a block diagram illustrating a configuration example of a data analysis apparatus 1 according to the present embodiment. The data analysis apparatus 1 uses data generated in various facilities such as a semiconductor manufacturing line, for example, and extracts, regarding a specific feature amount (a first feature amount) as an objective variable, another feature amount (a second feature amount) that is a variation factor of that objective variable as an explanatory variable. Further, the data analysis apparatus 1 calculates a regression coefficient by performing regression analysis of the explanatory variable. The objective variable can be represented by a regression equation (a regression model) using the explanatory variables and the regression coefficients.

Analysis-target data includes, for example, a measured value (a sensor value) acquired from a sensor installed in the semiconductor manufacturing line, and a set value set by an administrator such as a process condition or a target value. Therefore, the data is data of various feature amounts (types) and is super-high-dimensional data.

The feature amounts indicate types, features, and categories of the data and are, for example, parameters such as measured values or set values of a temperature, a pressure, a film thickness, and the like. Therefore, the feature amounts may be also referred to as parameters below. The number of feature amounts included in the analysis-target data is not specifically limited, and may be 1000 or more in the semiconductor manufacturing line.

A feature amount of the analysis-target data, which is particularly important for quality, is monitored at all times. In quality management, a variation factor (the second feature amount: the explanatory variable) is specified in order to detect a variation of this important feature amount (the first feature amount: the objective variable) or a sign of the variation. The data analysis apparatus 1 supports specifying of the variation factor of this important feature amount.

The data analysis apparatus 1 according to the present embodiment is described below.

The data analysis apparatus 1 includes an arithmetic processor 10, a database 20, a memory 30, and a user interface 40.

The arithmetic processor 10 extracts an explanatory variable that is a variation factor of an objective variable based on analysis-target data that is accumulated in the database 20, and performs regression analysis of the explanatory variable to calculate a regression coefficient. The arithmetic processor 10 includes an extractor 11, an adjuster 12, and an analyzer 13. It suffices that the arithmetic processor 10 is configured by, for example, one or a plurality of CPUs (Central Processing Units).

The database 20 stores therein data sampled for various feature amounts (parameters). The data is to be analyzed by the data analysis apparatus 1. Pieces of the data are associated with corresponding parameters, respectively, and can be selected for each parameter.

The memory 30 stores therein a program that causes the arithmetic processor 10 to perform regression analysis according to the present embodiment, a threshold used for data analysis according to the present embodiment, and the like. Further, the memory 30 can temporarily store data in the middle of analysis and a calculation result therein.

The user interface 40 has a function as an input portion to which a user inputs various set values and a function as a display that displays the explanatory variable and the regression coefficient obtained by regression analysis.

Functions of the arithmetic processor 10 and a data analysis method according to the present embodiment are described below.

### (Parameter Extraction)

The extractor 11 acquires data stored in the database 20. The extractor 11 uses the acquired data and extracts, regarding one important feature amount (hereinafter, also “important feature amount”) of a plurality of feature amounts (parameters) as an objective variable, one or a plurality of other feature amounts having a linear relation or a nonlinear relation with the important feature amount as one or a plurality of explanatory variables. The extracted feature amount is a parameter that affects the important feature amount and has a linear relation or a nonlinear relation with the important feature amount.

In a semiconductor manufacturing process, the number P of explanatory variables (the number of parameters) may be larger than the number N of sampled data pieces, and if regression analysis is performed as it is, a regression equation cannot be accurately derived. Alternatively, it may be impossible to narrow down a parameter related to the important feature amount.

Therefore, in the present embodiment, not only a parameter having a linear relation with the important feature amount (a linear parameter) but also a parameter having a nonlinear relation (a nonlinear parameter) is extracted. Statistical methods for extracting the linear parameter and the nonlinear parameter include DC-SIS (Sure Independence Screening procedure based on the Distance Correlation), sup-HSIC-SIS (Hilbert Schmidt independence criterion Sure Independence Screening), Random Forest, and the like.

DC-SIS is briefly described below. DC-SIS is an extension of SIS that performs extraction based on the Pearson correlation coefficient, and is used for measuring independence between two variables. It is assumed that certain observation data is (x, y)={(xᵢ, yᵢ): i=1, 2, . . . , n}. First, when calculation is performed for x, the following Expressions 1 to 4 are obtained.

$$\begin{matrix}[ Expression 1 ] & \\ {a}_{ij} = {\vert {x}_{i} - {x}_{j} \vert}_{p} & ( 1 ) \\ [ Expression 2 ] & \\ \overline{{a}_{i} .} = \frac{1}{n} {\sum }_{j}^{n} {a}_{ij} & ( 2 ) \\ [ Expression 3 ] & \\ \overline{a {.}_{j}} = \frac{1}{n} {\sum }_{i}^{n} {a}_{ij} & ( 3 ) \\ [ Expression 4 ] & \\ \overline{a ..} = \frac{1}{{n}^{2}} {\sum }_{i , j = 1}^{n} {a}_{ij} & ( 4 )\end{matrix}$$

Here aᵢⱼ is a difference (a distance) between x components of two pieces of observation data. In Expression 2, aᵢ.(bar) is an average of distances between xᵢ and x components of respective pieces of observation data. In Expression 3, a.ⱼ(bar) is an average of distances between xⱼ and x components of respective pieces of observation data. In Expression 4, a..(bar) is a value obtained by dividing the sum of the distances between xᵢ and the x components of the respective pieces of observation data and the distances between xⱼ and the x components of the respective pieces of observation data by n². From the above expressions, a centered distance matrix Aᵢⱼ is obtained as in Expression 5.

[Expression 5]

Aᵢⱼ=aᵢⱼ−aᵢ.−a.ⱼ+a.. (5)

A similar calculation is also performed for y, so that a distance matrix Bᵢⱼ is obtained as in Expression 6.

[Expression 6]

Bᵢⱼ=bᵢⱼ−bᵢ.−b.ⱼ+b.. (6)

The following Expressions 7 to 9 are obtained from the distance matrices Aᵢⱼ and Bᵢⱼ, and a DC value represented by Expression 10 is obtained.

$$\begin{matrix}[ Expression 7 ] & \\ d Cov ( x , x ) = \frac{1}{{n}^{2}} {\sum }_{i , j = 1}^{n} {A}_{ij}^{2} & ( 7 ) \\ [ Expression 8 ] & \\ d Cov ( y , y ) = \frac{1}{{n}^{2}} {\sum }_{i , j = 1}^{n} {B}_{ij}^{2} & ( 8 ) \\ [ Expression 9 ] & \\ d Cov ( x , y ) = \frac{1}{{n}^{2}} {\sum }_{i , j = 1}^{n} {A}_{ij} {B}_{ij} & ( 9 ) \\ [ Expression 10 ] & \\ d Corr ( x , y ) = \frac{d Cov ( x , y )}{\sqrt{d Cov ( x , x ) d Cov ( y , y )}} ( = DC ) & ( 10 )\end{matrix}$$

The DC value is a value in a range of 0 to 1 (0≤DC≤1). The DC value closer to 1 means that two variables (x, y) has a stronger relation therebetween, and the DC value closer to 0 means that the relation between the two variables (x, y) is weaker (the two variables are independent of each other). Not only for a linear relation but also for a nonlinear relation, the DC value can indicate a relation between the two variables (x, y).

The extractor 11 obtains a DC value between an important feature amount and another parameter by using DC-SIS described above.

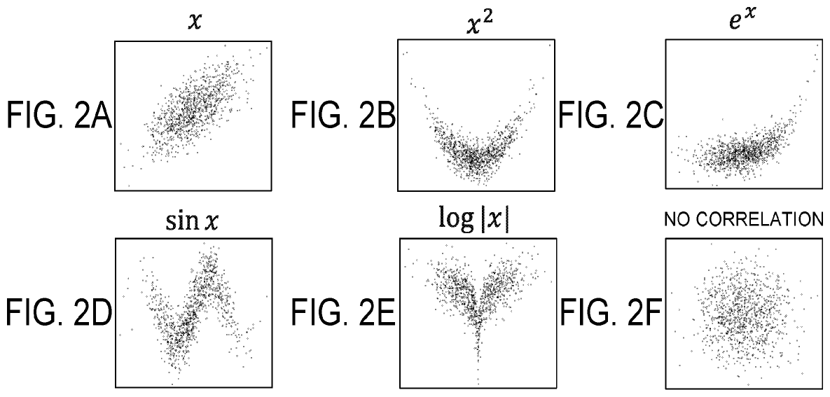

FIGS. 2A to 2F are graphs illustrating specific examples of a parameter x and an important feature amount y. For example, the horizontal axis represents x and the vertical axis represents y in each graph. In FIG. 2A, the parameter (the explanatory variable) x has a linear relation with the important feature amount (the objective variable) y. In FIGS. 2B to 2E, the parameter x has a nonlinear relation with the important feature amount y. The important feature amount y relates to a parameter x² in FIG. 2B, a parameter e^{x} in FIG. 2C, a parameter sin x in FIG. 2D, and a parameter log|x| in FIG. 2E. FIG. 2F indicates that the parameter x has no relation (no correlation) with the important feature amount y.

A DC value indicates the degree of relation between each parameter (for example, x, x², e^{x}, sin x, or log|x|) and the important feature amount y.

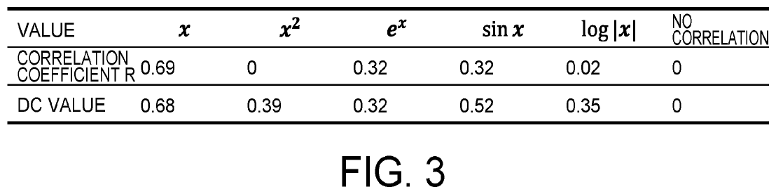

FIG. 3 is a table representing an example of a correlation coefficient between the parameter x and the important feature amount y and a DC value. FIG. 3 represents results of calculation of the degree of relation between the important feature amount y and the parameters (x, x², e^{x}, sin x, log|x|, and no correlation) respectively having relations illustrated in FIGS. 2A to 2F by SIS that constructs a linear model (hereinafter, also “linear SIS”) and DC-SIS. A correlation coefficient R indicates the result of calculation using linear SIS. The correlation coefficient R is a value in a range of −1 to 1 (−1≤R≤1) and means that two variables has a stronger relation as the absolute value of R is closer to 1, and the relation between the two variables is weaker (the two variables are independent of each other) as the absolute value of R is closer to 0. The DC value indicates the result of calculation using DC-SIS, as described above. That is, FIG. 3 represents a correlation coefficient R and a DC value for y=x, a correlation coefficient R and a DC value for y=x², a correlation coefficient R and a DC value for y=e^{x}, a correlation coefficient R and a DC value for y=sin x, a correlation coefficient R and a DC value for y=log|x|, and a correlation coefficient R and a DC value when there is no correlation. Therefore, in FIG. 3, it is preferable that the correlation coefficient R and the DC value for any of the parameters other than the parameter having no correlation are close to 1.

The correlation coefficient R is relatively large (0.69) for the parameter x that has a linear relation (y=x) with the important feature amount y. Meanwhile, the correlation coefficient R is relatively small (0, 0.32, 0.32, 0.02) for the parameters (x², e^{x}, sin x, and log|x|) that respectively have nonlinear relations (y=x², y=e^{x}, y=sin x, and y=log|x|) with the important feature amount y.

Meanwhile, for the parameter x having a linear relation (y=x) with the important feature amount y, the DC value is a large value (0.68) that is substantially equal to the correlation coefficient R. Further, the DC values are relatively large (0.39, 0.32, 0.52, and 0.35) also for the parameters (x², e^{x}, sin x, and log|x|) respectively having nonlinear relations (y=x², y=e^{x}, y=sin x, and y=log|x|) with the important feature amount y.

As described above, the DC value is more preferable than the correlation coefficient R as an indicator value that indicates the degree of relation between each of parameters (for example, x, x², e^{x}, sin x, and log|x|) having a linear relation and a nonlinear relation with the important feature amount y. In the present embodiment, the extractor 11 extracts a parameter (that is, an explanatory variable) used in a regression equation for the important feature amount y based on the DC value.

For example, the extractor 11 extracts a parameter having a DC value larger than a predetermined threshold as an explanatory variable. Alternatively, the extractor 11 may extract a predetermined number of parameters in descending order of DC value, as explanatory variables. It suffices that the threshold or the predetermined number is preset and stored in the memory 30.

FIG. 3 represents results of trials of linear SIS and DC-SIS using the parameters that have already been found to have a linear relation and a nonlinear relation as illustrated in FIGS. 2A to 2F. Actually, at this extraction stage, although it is possible to know whether each parameter (each feature amount) has a strong relation with the objective variable y, it is not possible to know which of a linear relation and a nonlinear relation each parameter has with the objective variable y. Therefore, although the extractor 11 extracts a parameter (a feature amount) having a strong relation with the objective variable y based on a DC value, it has not been found at this stage whether the extracted parameter has a linear relation or a nonlinear relation with the objective variable y.

### (Parameter Adjustment)

The adjuster 12 performs, using the parameters extracted by the extractor 11, linear regression of data of the respective parameters and nonlinear regression of data of the respective parameters. Further, the adjuster 12 compares the obtained results of linear regression and nonlinear regression with each other to perform a test, and sets the number of nodes of base conversion for each parameter based on a significant difference between the obtained results.

Here, it can be also considered to simply perform regression analysis for the parameters extracted by the extractor 11 by Lasso that uses B-spline base conversion (hereinafter, “B-spline Lasso”). In this case, however, since all the parameters are subjected to B-spline base conversion, a linear parameter that does not need to be subjected to B-spline base conversion is also subjected to B-spline base conversion. When B-spline base conversion is performed, each parameter is divided by a predetermined number of nodes, and therefore the number of nodes increases and the number of parameters (explanatory variables) may become larger than the number of sampled data pieces. When the number of parameters is larger than the number of sampled data pieces, reliability of regression analysis is lowered. Further, since division by a predetermined number of nodes is performed for all the extracted parameters, the number of divisions is not optimized for each parameter. This also causes decrease of reliability of regression analysis. Furthermore, since the data size increases with increase of the number of nodes, a calculation time of regression analysis may become enormous. Although it can be considered that parallel processing of regression analysis is performed in terms of algorithm, parallel processing of data having a large data size requires an enormous memory capacity.

Meanwhile, according to the present embodiment, the adjuster 12 determines whether each extracted parameter is a linear parameter or a nonlinear parameter by a test. Further, in a case where the parameter is a linear parameter, the adjuster 12 does not set a node of base conversion. In this case, the adjuster 12 sets the number of nodes to zero. On the contrary, in a case where the parameter is a nonlinear parameter, the adjuster 12 sets a node of base conversion. In this case, the adjuster 12 sets the number of nodes by a coefficient of determination descried later.

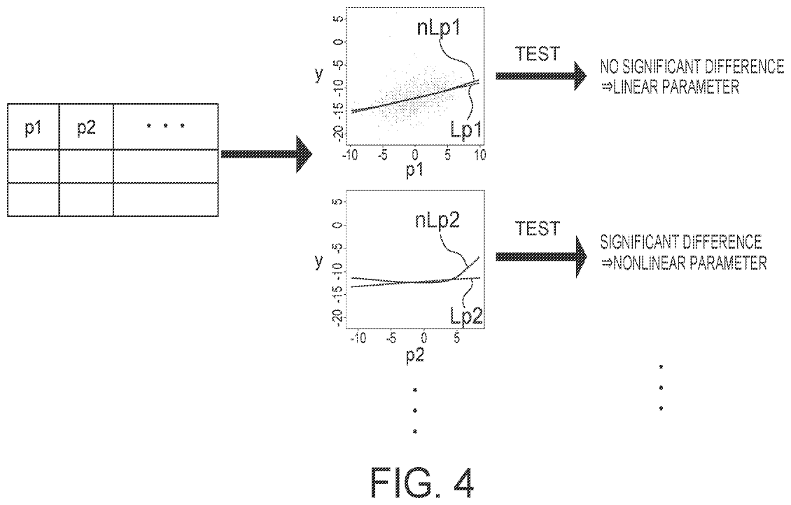

FIG. 4 is a conceptual diagram illustrating a method of determining whether a parameter is a linear parameter or a nonlinear parameter. In the present embodiment, the adjuster 12 divides sample data into training data and verification data at a ratio of 9:1, for example. The adjuster 12 performs determination, for each training data piece, whether it Is a linear parameter or a nonlinear parameter by the following method and performs regression analysis, and thereafter calculates a coefficient of determination using verification data of a nonlinear parameter and verifies accuracy of an obtained regression model.

It is assumed that continuous variables (a linear parameter and a nonlinear parameter) and a category variable are included in the parameters extracted by the extractor 11. The category variable is a variable representing a category to which a corresponding piece of data belongs by a discrete value, and is usually represented in binary using 0 or 1. First, the adjuster 12 extracts only the continuous variables except for the category variable. For example, in FIG. 4, It Is assumed that parameters p1, p2, . . . are output as the continuous variables.

Next, the adjuster 12 performs linear regression (simple regression analysis) for training data of the parameters p1, p2, . . . to obtain linear regression results Lp1, Lp2, . . . of the respective parameters. For linear regression, a generalized linear model (GLM) is used, for example. In addition, the adjuster 12 performs nonlinear regression by spline smoothing for each parameter to obtain nonlinear regression results nLp1, nLp2, . . . of the respective parameters. For nonlinear regression, a generalized additive model (GAM) is used, for example.

The adjuster 12 performs an Anova test (analysis of variance) for the linear regression results Lp1, Lp2, . . . and the nonlinear regression results nLp1, nLp2, . . . of the parameters p1, p2, . . . and calculates significant differences between the linear regression results Lp1, Lp2, . . . and the nonlinear regression results nLp1, nLp2, . . . . The adjuster 12 determines that there is a significant difference when a p-value is lower than a significance level, and determines that there is no significant difference when the p-value is higher than the significance level. When determining that there is a significant difference, the adjuster 12 determines that the parameter is a nonlinear parameter. When determining that there is no significant difference, the adjuster 12 determines that the parameter is a linear parameter. For example, in FIG. 4, It has been determined that there is no significant difference between the linear regression result Lp1 and the nonlinear regression result nLp1 and therefore the parameter p1 is a linear parameter. It has been determined that there is a significant difference between the linear regression result Lp2 and the nonlinear regression result nLp2 and therefore the parameter p2 is a nonlinear parameter.

At this time, a threshold for a nonlinear component detected by Anova is adjusted with the significance level. The memory 30 stores a preset significance level therein. Further, the memory 30 stores therein information about whether each of the parameters p1, p2, . . . is a linear parameter or a nonlinear parameter.

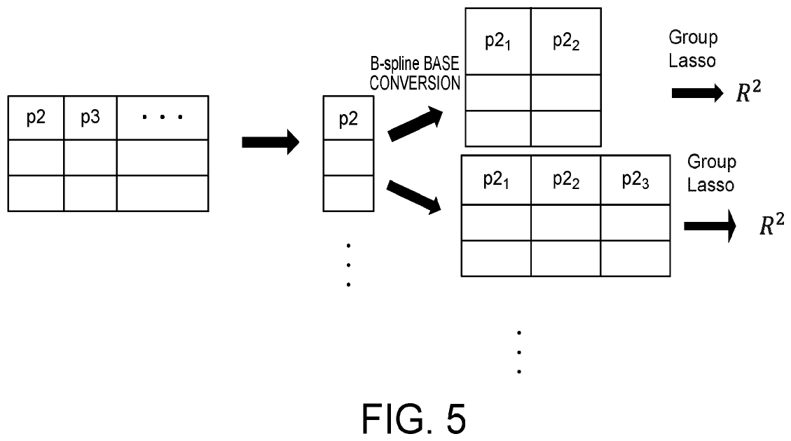

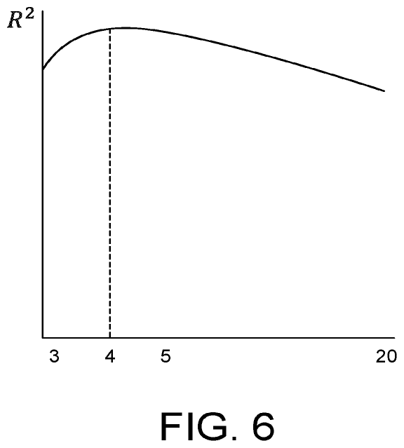

FIGS. 5 and 6 are conceptual diagrams illustrating a method of setting the number of nodes for a nonlinear parameter. Setting of the number of nodes of base conversion is described in detail with reference to FIGS. 5 and 6.

For the linear parameters p1, . . . , the adjuster 12 does not set a node of B-spline base conversion. Meanwhile, for the nonlinear parameters p2, . . . , the adjuster 12 sets a node of B-spline base conversion. Further, the adjuster 12 sets the number of nodes based on a coefficient of determination obtained by performing regression analysis of data of the nonlinear parameters p2, . . . . Setting of the number of nodes for the nonlinear parameter p2 is described in more detail below. The maximum value of the number of nodes (for example, 20) is preset and stored in the memory 30.

The adjuster 12 gives the numbers of nodes from 1 to 20 to data by using B-spline Lasso, and creates a regression model (a nonlinear model) for each number of nodes. In the present embodiment, since the number of nodes is determined for each nonlinear parameter, the capacity of the memory 30 can be relatively small even when calculation is performed in parallel. Therefore, setting of the number of nodes for each nonlinear parameter can be calculated in parallel even with a small memory capacity, and a calculation time can be shortened.

The adjuster 12 performs regression analysis (B-spline Lasso) while changing the number of nodes for training data of each nonlinear parameter, thereby creating a regression model and calculates a coefficient of determination R² using data of that regression model. The coefficient of determination R² is the square of the correlation coefficient R and is a value in a range of 0 to 1 (0≤R²≤1). The coefficient of determination R² means that as it is closer to 1, two variables (p, y) have a stronger relation therebetween, and as it is closer to 0, the relation between the two variables (p, y) is weaker. Therefore, the adjuster 12 sets the number of nodes at which the coefficient of determination R² is maximum, as the number of nodes for each nonlinear parameter.

For example, the coefficient of determination R² for the nonlinear parameter p2 is illustrated in the graph in FIG. 6. The horizontal axis represents the number of nodes and the vertical axis represents the coefficient of determination R². In this graph, the coefficient of determination R² is maximum when the number of nodes is four. Therefore, the adjuster 12 sets the number of nodes of B-spline base conversion for the nonlinear parameter p2 to four. It suffices that the number of nodes is stored in the memory 30.

After setting the number of nodes, the adjuster 12 determines node positions for each nonlinear parameter based on the data density of that nonlinear parameter. For example, the adjuster 12 determines the node positions in such a manner that data of the nonlinear parameter p2 is divided substantially equally. That is, when the number of nodes is four, it suffices that the adjuster 12 determines the node positions in such a manner that data of the nonlinear parameter p2 is divided into five parts including the same number of data pieces as each other.

### (Data Analysis)

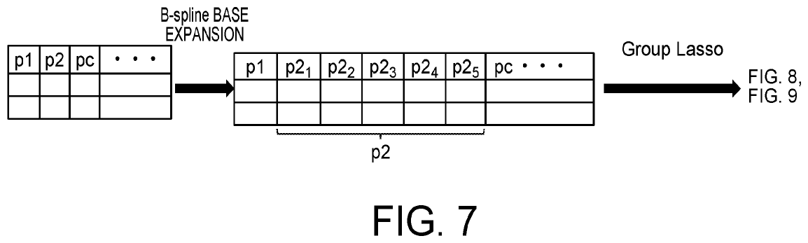

FIG. 7 is a conceptual diagram illustrating data analysis according to the present embodiment. The analyzer 13 divides a nonlinear parameter based on a node set by the adjuster 12 and performs regression analysis, thereby generating a regression equation in which the important feature amount y is represented by parameters.

More specifically, the analyzer 13 does not divide the linear parameters p1, . . . among all the parameters extracted by the extractor 11. For each of the nonlinear parameters p2, . . . , the analyzer 13 performs division by the number of nodes set for that parameter and performs regression analysis using B-spline Lasso. Therefore, in the present embodiment, the analyzer 13 performs B-spline base expansion only for the nonlinear parameters p2, . . . and performs division by the number of nodes set by the adjuster 12. For the linear parameters p1, . . . and a category variable pc, the analyzer 13 does not perform B-spline base expansion. The nonlinear parameter p2 subjected to B-spline base expansion is divided into five parameters p2₁, p2₂, p2₃, p2₄, and p2s in accordance with the number of nodes, four, set by the adjuster 12.

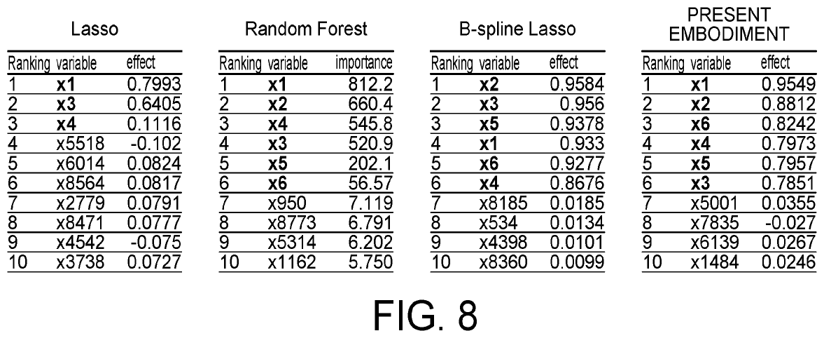

Further, the analyzer 13 performs Group Lasso by regarding the parameters p2₁, p2₂, p2₃, p2₄, and p2₅ as Group, and performs regression analysis. Thus, a regression coefficient is obtained for the parameter extracted by the extractor 11. As a result, a regression model is obtained with regard to the important feature amount y. For example, regression coefficients illustrated in FIG. 8 have been obtained. It suffices that the user interface 40 displays the parameters and the regression coefficients illustrated in FIG. 8, for example. In the analyzer 13, various algorithms are executed in parallel as a sequence of analyzing super-high-dimensional nonlinear data. Therefore, the analyzer 13 also performs another nonlinear analysis method such as Random Forest.

### (B-Spline Lasso)

B-spline Lasso is briefly described below.

B-spline Lasso is a method obtained by combining the least squares method, an additive model, and regularization together.

First, the least squares method is described. For n samples xᵢ and yᵢ (i=1 to n), a linear regression model (GLM (Generalized Linear Model)) is represented by the following Expression 11.

[Expression 11]

yₗ=β₀+xᵢ₁β₁+xᵢ₂β₂+ . . . +xᵢₚβₚ+εᵢ (i=1,2 . . . n) (11)

where β₀ represents an intercept, β₁ to βₚ represent regression coefficients, and ε is an observation error that follows a normal distribution with an average of 0 and a standard deviation of 1. In addition, substitution of terms in Expression 11 using Expressions 12 to 16 and centralization lead to Expression 16.

[Expression 12]

β=(β₁,β₂ . . . βₚ)^{T} (12)

[Expression 13]

y=(y₁,y₂ . . . yₙ)^{T} (13)

[Expression 14]

X=(x₍₁₎,x₍₂₎ . . . x₍ₚ₎) (14)

[Expression 15]

x₍ⱼ₎=(x₁ⱼ,x₂ⱼ . . . xₙⱼ)^{T} (15)

[Expression 16]

y=Xβ+ε ε˜N(0.1) (16)

The regression coefficients β₁ to βₚ can be obtained by minimizing the square of the error ε (the square error) in Expression 11. That is, the regression coefficients β₁ to βₚ are obtained by solving Expression 17. This method is called the least squares method.

$$\begin{matrix}[ Expression 17 ] & \\ min {‖ ɛ ‖}_{2}^{2} = {min}_{β} {‖ y - X β ‖}_{2}^{2} & ( 17 )\end{matrix}$$

At this time, ∥y−Xβ∥ represents the L₂ norm and is represented by Expression 18.

[Expression 18]

∥y−Xβ∥₂=\sqrt{|y₁−x₁β₁|²+|y₂−x₂β₂|²+, . . . ,+|yₚ−xₚβₚ|²} (18)

Next, an additive model is described.

A generalized additive model GAM using a basis function can express a nonlinear component. The generalized additive model is a method of expressing a nonlinear component by adding complicated functions that cannot be linearly described together. The basis function is each of functions to be added together. An expression using a B-spline (Basis spline) basis function is represented by Expression 19.

$$\begin{matrix}[ Expression 19 ] & \\ {y}_{i} = {\sum }_{j = 1}^{p} {\sum }_{m = 1}^{{M}_{j}} {β}_{jm} {B}_{jm} ( {x}_{i} ) ( i = 1 , 2 , … , n ) & ( 19 )\end{matrix}$$

Expression 19 is obtained by converting each variable xᵢ by a B-spline basis function Bₘ, and βⱼₘ represents a regression coefficient. The B-spline basis function can be locally represented by a polynomial by dividing a B-spline curve at nodes. Therefore, the B-spline basis function can express a nonlinear component. The regression coefficient βⱼₘ that minimizes an error with regard to Expression 19 can be obtained by solving a minimization problem represented by Expression 20.

$$\begin{matrix}[ Expression 20 ] & \\ {min}_{{β}_{im}} {( {y}_{i} - {\sum }_{j = 1}^{p} {\sum }_{m = 1}^{{M}_{j}} {β}_{jm} {β}_{jm} ( {x}_{i} ) )}^{2} ( i = 1 , 2 , … , n ) & ( 20 )\end{matrix}$$

Next, regularization is described.

When the number of sample data pieces is smaller than the number of explanatory variables (parameters), Expression 17 has an infinite number of solutions. When the number of equations is small as described above, an optimum solution is obtained by solving a minimization problem under a constraint. At this time, an expression obtained by adding norms of the regression coefficients β₁ to βₚ as penalty terms to Expression 17 is minimized as a constraint. This minimization problem is represented by Expression 21.

$$\begin{matrix}[ Expression 21 ] & \\ {min}_{β} {‖ y - X β ‖}_{2}^{2} + λ {‖ β ‖}_{1} & ( 21 )\end{matrix}$$

Such a constrained minimization problem is called Lasso. ∥β∥₁ represents the L₁ norm represented by Expression 22. λ is a regularization parameter.

[Expression 22]

∥β∥₁=|β₁|+|β₂|+ . . . +|βₚ| (22)

Further, as an application of Lasso, group information can be included in explanatory variables. For example, in a process performed by a plurality of devices, Group Lasso is used when variable selection is performed for each group of the devices of the entire process. Group Lasso is given by Expression 23.

$$\begin{matrix}[ Expression 23 ] & \\ {min}_{β} {‖ y - {\sum }_{j = 1}^{j} {X}_{j} {β}_{j} ‖}_{2}^{2} λ {\sum }_{j = 1}^{j} {( {β}_{j}^{T} {Ω}_{j} {β}_{j} )}^{1 / 2} & ( 23 )\end{matrix}$$

This expression indicates that explanatory variables are divided into J group variables, and Ωⱼ is a non-negative definite matrix (positive-semidefinite matrix). B-spline Lasso can be represented by Expression 24 from Expressions 20 and 23.

$$\begin{matrix}[ Expression 24 ] & \\ {min}_{{β}_{im}} {( {y}_{i} - {\sum }_{j = 1}^{p} {\sum }_{m = 1}^{{M}_{j}} {β}_{jm} {β}_{jm} ( {x}_{i} ) )}^{2} + λ {\sum }_{j = 1}^{J} {( {β}_{j}^{T} {Ω}_{j} {β}_{j} )}^{1 / 2} ( i = 1 , 2 , … , n ) & ( 24 )\end{matrix}$$

where βⱼ is represented by Expression 25.

[Expression 25]

βⱼ=(βⱼ₁,βⱼ₂, . . . ,βjMⱼ) (25)

Group Lasso handles each explanatory variable as a group, and sets explanatory variables after each explanatory variable is subjected to expansion by a B-spline basis function, as elements of the group.

### (Evaluation of Present Embodiment)

In order to evaluate a regression model of the data analysis apparatus 1 according to the present embodiment, the following data was artificially created. The number of sample data pieces is 1000. The average of the data pieces is 0. The sample data was generated from random numbers following a normal distribution with a standard deviation of 3. The total number of parameters (explanatory variables) is 10000. At this time, a relation between the important feature amount (the objective variable) y and each parameter is set by Expression 26.

[Expression 26]

y=x₁+x₂²+x₃³+e^{x}^{₆}+log|x₅|+sin x₆+ε ε˜N(0.3) (26)

According to Expression 26, the objective variable y is a variable obtained by adding a linear parameter x₁ and nonlinear parameters x₂², x₃³, e^{x4}, log|x₅|, sin x₆, and ε with coefficients of 1. In this expression, ε is an error value. x₇ and subsequent parameters are noise parameter having no correlation with y.

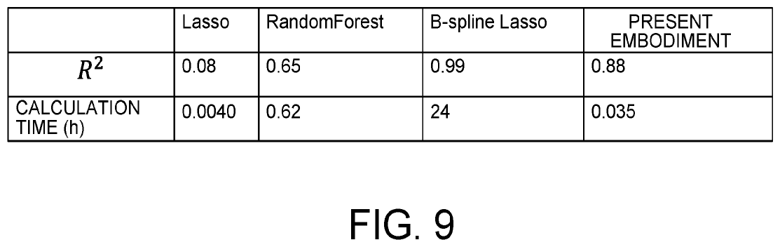

Under this setting, the extractor 11 first divides the sample data into training data and verification data, for example, at a ratio of 9:1. The arithmetic processor 10 performs regression analysis for the training data by using each of Lasso, Random Forest, B-spline Lasso, and the data analysis method according to the present embodiment described above. Next, based on regression coefficients of the respective parameters calculated by each method, Influences of the respective parameters on y were arranged in descending order. In the above setting, as represented by Expression 26, the coefficients (effects) of the parameters x₁, x₂², x₃³, e^{x4}, log|x₅|, and sin x₆ are set to 1, and the noise parameters after x₇ are set to 0. Further, accuracy of a regression model of each method was verified by calculating R² with the verified data. The results are represented in FIGS. 8 and 9.

FIG. 8 represents tables of regression coefficients obtained by Lasso, Random Forest, B-spline Lasso, and the data analysis method according to the present embodiment. FIG. 9 represents a table of coefficients of determination R² and calculation times obtained by Lasso, Random Forest, B-spline Lasso, and the data analysis method according to the present embodiment. Since importance is listed with regard to Random Forest, Random Forest cannot be compared with the other methods in FIG. 8, but can be compared with the other methods in FIG. 9. Here, importance indicates the degree of importance of each explanatory variable with respect to an objective variable.

With reference to FIG. 8, in Lasso, extracted parameters are x₁, x₃³, and e^{x4} only, and parameters are not correctly extracted. This is because Lasso is a method that performs linear regression only and does not consider a nonlinear parameter. B-spline Lasso and the method according to the present embodiment correctly extract the parameters x₁, x₂², x₃³, e^{x4}, log|x₅|, and sin x₆.

With reference to the coefficients of determination R² in FIG. 9, a method that constructs the closest regression model to Expression 26 is B-spline Lasso. That is, the regression coefficient of B-spline Lasso (effect) is close to 1 for any of the parameters x₁, x₂², x₃³, e^{x4}, log|x₅|, and sin x₆, and B-spline Lasso constructs the closest regression model to Expression 26. The method according to the present embodiment constructs the second closest regression model to Expression 26. Further, the accuracy decreases in the order of Random Forest and Lasso.

Meanwhile, as for the calculation time, Lasso has the shortest time and the method according to the present embodiment has the second shortest time. Further, it is found that the calculation time becomes longer in the order of Random Forest and B-spline Lasso. In particular, although B-spline Lasso has high accuracy in the coefficient of determination R², it takes 24 hours for calculation. This is because B-spline Lasso performs B-spline base conversion for all explanatory variables without distinguishing a linear parameter and a nonlinear parameter from each other and therefore the number of explanatory variables is large, and because an optimal model is searched for plural numbers of nodes.

On the other hand, the coefficient of determination R² of the method according to the present embodiment is 0.88, which is smaller than the coefficient of determination R² of B-spline Lasso (0.99) but is sufficiently large. Meanwhile, the calculation time of the method according to the present embodiment is 0.035 hour, which is overwhelmingly shorter than the calculation time (24 hours) of B-spline Lasso. Therefore, it can be said that the data analysis apparatus 1 according to the present embodiment can construct a regression model with relatively high reliability in a short time. That is, the data analysis apparatus 1 according to the present embodiment can achieve reliability of a regression model and reduction of a regression analysis time at the same time.

This evaluation was performed while the number of sample data pieces and the number of parameters (feature amounts) were limited as described above. In practice, the data analysis apparatus 1 may perform regression analysis using more data pieces and more parameters. Therefore, reduction of a regression analysis time can be an important factor in selection of a regression analysis method, as well as reliability of a regression model obtained by regression analysis. Under such circumstances, it can be said that the data analysis apparatus 1 according to the present embodiment is superior to a conventional analysis method such as B-spline Lasso.

At least a part of the data analysis method in the data analysis apparatus according to the present embodiment can be constituted by hardware or software. When it is constituted by software, it is possible to configure that a program for realizing at least a part of the functions of the data analysis method is stored in a recording medium such as a flexible disk or a CD-ROM, and the program is read and executed by a computer. The recording medium is not limited to a detachable device such as a magnetic disk or an optical disk, and can be a fixed recording medium such as a hard disk device or a memory. Further, the program for realizing at least a part of the functions of the data analysis method can be distributed via a communication line (including wireless communication) such as the Internet. Furthermore, the program can be distributed in an encrypted, modulated, or compressed state via a wired line or a wireless line such as the Internet, or the program can be distributed as it is stored in a recording medium.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A data analysis apparatus comprising:
an extractor configured to extract, regarding a first feature amount among a plurality of feature amounts as an objective variable, a second feature amount having a linear relation or a nonlinear relation with the first feature amount as an explanatory variable by using analysis-target data that is sampled for the feature amounts;
an adjuster configured to set a node of base conversion for the second feature amount based on a significant difference between a linear regression result obtained by linear regression of the second feature amount and a nonlinear regression result obtained by nonlinear regression of the second feature amount; and
an analyzer configured to divide the second feature amount based on the node set by the adjuster and perform regression analysis to generate a regression equation that represents the objective variable by the explanatory variable.

2. The apparatus of claim 1, wherein the extractor extracts the second feature amount based on indicator values each indicating a linear relation or a nonlinear relation of a corresponding one of the feature amounts with respect to the first feature amount.

3. The apparatus of claim 2, wherein the extractor extracts the feature amount having the indicator value larger than a first threshold as the second feature amount, or extracts a predetermined number of the feature amounts in descending order of the indicator values as the second feature amounts.

4. The apparatus of claim 1, wherein the adjuster performs analysis of variance of the linear regression result and the nonlinear regression result to obtain the significant difference.

5. The apparatus of claim 1, wherein the adjuster determines that the second feature amount is a linear explanatory variable having a linear relation with the first feature amount and sets no node of base conversion when there is no significant difference between the linear regression result and the nonlinear regression result, and determines that the second feature amount is a nonlinear explanatory variable having a nonlinear relation with the first feature amount and sets the node of base conversion for the second feature amount when there is the significant difference.

6. The apparatus of claim 5, wherein, when the second feature amount is a nonlinear explanatory variable, the adjuster sets number of the nodes based on a coefficient of determination obtained by regression analysis of the second feature amount.

7. The apparatus of claim 6, wherein the adjuster sets the number of the nodes when the coefficient of determination is maximum, as the number of the nodes for the second feature amount.

8. The apparatus of claim 5, wherein the adjuster determines a node position for the second feature amount based on a density of the analysis-target data of the second feature amount.

9. The apparatus of claim 5, wherein the adjuster determines a node position for the second feature amount in such a manner that the analysis-target data of the second feature amount is divided substantially equally.

10. The apparatus of claim 5, wherein the analyzer performs no division of the second feature amount when the second feature amount is a linear explanatory variable, and
divides the second feature amount into parts, the number of which is in accordance with the node, and performs regression analysis when the second feature amount is a nonlinear explanatory variable.

11. The apparatus of claim 1, wherein the extractor, the adjuster, and the analyzer are configured in an arithmetic processor, and the apparatus further comprises:
a memory configured to store therein a program that causes the arithmetic processor to perform the regression analysis; and
a database configured to store the analysis-target data therein.

12. The apparatus of claim 1, further comprising a display configured to display the explanatory variable related to the objective variable and a regression coefficient of the explanatory variable by regression analysis by the analyzer.

13. A data analysis method using a data analysis apparatus including an arithmetic processor, the method comprising:
extracting, regarding a first feature amount among a plurality of feature amounts as an objective variable, a second feature amount having a linear relation or a nonlinear relation with the first feature amount as an explanatory variable by using analysis-target data that is sampled for the feature amounts;
determining whether the second feature amount has a linear relation or a nonlinear relation with the first feature amount, and setting a node of base conversion for the second feature amount when the second feature amount has a nonlinear relation with the first feature amount; and
dividing the second feature amount based on the node and performing regression analysis to generate a regression equation that represents the objective variable by the explanatory variable.

14. The method of claim 13, wherein the second feature amount is extracted based on indicator values each indicating a linear relation or a nonlinear relation of a corresponding one of the feature amounts with respect to the first feature amount.

15. The method of claim 14, wherein the feature amount having the indicator value larger than a first threshold is extracted as the second feature amount, or a predetermined number of the feature amounts are extracted in descending order of the indicator values as the second feature amounts.

16. The method of claim 15, wherein it is determined whether the second feature amount has a linear relation or a nonlinear relation with the first feature amount based on a significant difference between a linear regression result obtained by linear regression of the second feature amount and a nonlinear regression result obtained by nonlinear regression of the second feature amount.

17. The method of claim 16, wherein
the second feature amount is determined as a linear explanatory variable having a linear relation with the first feature amount and no node of base conversion is set, when there is no significant difference between the linear regression result and the nonlinear regression result, and
the second feature amount is determined as a nonlinear explanatory variable having a nonlinear relation with the first feature amount and the node of base conversion is set for the second feature amount, when there is the significant difference.

18. The method of claim 17, wherein, when the second feature amount is a nonlinear explanatory variable, number of the nodes is set based on a coefficient of determination obtained by regression analysis of the second feature amount.

19. The method of claim 18, wherein the number of the nodes when the coefficient of determination is maximum is set as the number of the nodes for the second feature amount.

20. The method of claim 17, wherein no division is performed for the second feature amount that is a linear explanatory variable, and
division into parts, number of which is in accordance with the node, and regression analysis are performed for the second feature amount that is a nonlinear explanatory variable.
